(19) United States
(12) Patent Application Publication
(10) Pub. No.: US 2007/0170962 A1
(43) Pub. Date: Jul. 26, 2007

(54) Low-power power-on reset circuit

(75) Inventor: Jean-Shin Wu, Shindian City (TW)

Correspondence Address: BACON & THOMAS, PLLC, 625 SLATERS LANE, FOURTH FLOOR, ALEXANDRIA, VA, 22314, US

(73) Assignee: California Micro Devices Corporation, Milpitas, CA (US)

(21) Appl. No.: 11/643,819

(22) Filed: Dec. 22, 2006

(30) Foreign Application Priority Data
Jan. 20, 2006 (TW) 095102184

(51) Int. Cl. H03L 7/00

(52) U.S. Cl. 327/143

(57) ABSTRACT

The low-power power-on reset circuit includes a NOT gate device, a time delay device, a wave shaping device and a NOR gate device, with which the present invention can provide a low power power-on reset circuit that can be formed by a complementary metal oxide semiconductor (CMOS), such that a lower power consumption and a higher noise margin can both be provided.

### BACKGROUND OF THE INVENTION

1. Field of the Invention

The present invention relates to a power-on reset circuit and, more particularly, to a low-power power-on-reset circuit applied to integrated circuits.

2. Description of Related Art

Registers and memory circuits are frequently used in conventional logic circuits (e.g. CPUs and memories); however, as the power is turned on, the stored data are often random and meaningless. In order to avoid any error that would have caused by reading such random data, a power-on reset circuit is conventionally employed to reset the stored data to become 0.

Also, as mentioned in the U.S. Pat. No. 6,259,284 granted to Hwang, et al. for a “Charge free power-on-reset circuit”, with reference to FIG. 1, a diagram illustrating the prior art system, and FIG. 2, the characteristic curve diagram of FIG. 1, the prior art relates to a power-on rest circuit comprised of a resistor 81 and a capacitor 82, with which the circuit can prevent from entering an active mode when powered on. As shown in FIG. 2, A is the ideal power-on voltage curve, while B is the actual voltage curve of the circuit. An exceedingly high capacitance is the major drawback for this type of circuit. When laying out an integrated circuit, it is not easy to carry out such high capacitance, and at the same time a considerable amount of space would be occupied. Besides, charging on the resistor 81 and the capacitor 82 by the power voltage 83 creates much more power consumption.

FIG. 3 is a schematic diagram illustrating another prior art, and FIG. 4 is the characteristic curve diagram for that in FIG. 3. In this prior art, the circuit replaces the resistor with a transistor 91. Despite the transistor 91 can be implemented more easily in the layout of an integrated circuit to reduce the high capacitance issue, the characteristic curve D in FIG. 4 is still not yet comparable to the ideal condition. Besides, charging the transistor 91 and the capacitor 92 by the power voltage 93 generates large power consumption as well.

Therefore, it is desirable to provide an improved low-power power-on reset circuit to mitigate and/or obviate the aforementioned problems.

### SUMMARY OF THE INVENTION

The objective of the present invention is to provide a low-power power-on reset circuit, which can be formed by complementary metal oxide semiconductor (CMOS) devices, such that lower power consumption and a higher noise margin can be provided.

To achieve the above objective, the present invention relates to a low-power power-on reset circuit, which comprises a NOT gate device, a time delay device, a wave shaping device and a NOR gate device.

The NOT gate device has an input and an output, and the input of the NOT gate device is configured to input a power voltage. The time delay device has an input and an output, and the input of the time delay device is electrically connected to the output of the NOT gate device. The wave shaping device has an input and an output, and the input of the wave shaping device is electrically connected to the output of the time delay device. The NOR gate device has a first input, a second input and an output. The first input is electrically connected to the output of the wave shaping device. The second input is electrically connected to the output of the NOT gate device, while a power-on reset signal is outputted from the output.

### BRIEF DESCRIPTION OF THE DRAWINGS

FIG. 1 is a schematic diagram of a prior power-on reset circuit;

FIG. 2 is a characteristic curve diagram illustrating the prior art in FIG. 1;

FIG. 3 is a schematic diagram of another prior power-on reset circuit;

FIG. 4 is a characteristic curve diagram illustrating the prior art in FIG. 3;

FIG. 5 is a schematic diagram depicting one embodiment of the present invention;

FIG. 6 is a circuit diagram depicting the embodiment of the present invention;

FIG. 7 shows a set of partially magnified waveforms in accordance with the embodiment of the present invention;

FIG. 8 shows a set of waveforms in accordance with the embodiment of the present invention; and

FIG. 9 is a schematic diagram depicting another embodiment of the present invention.

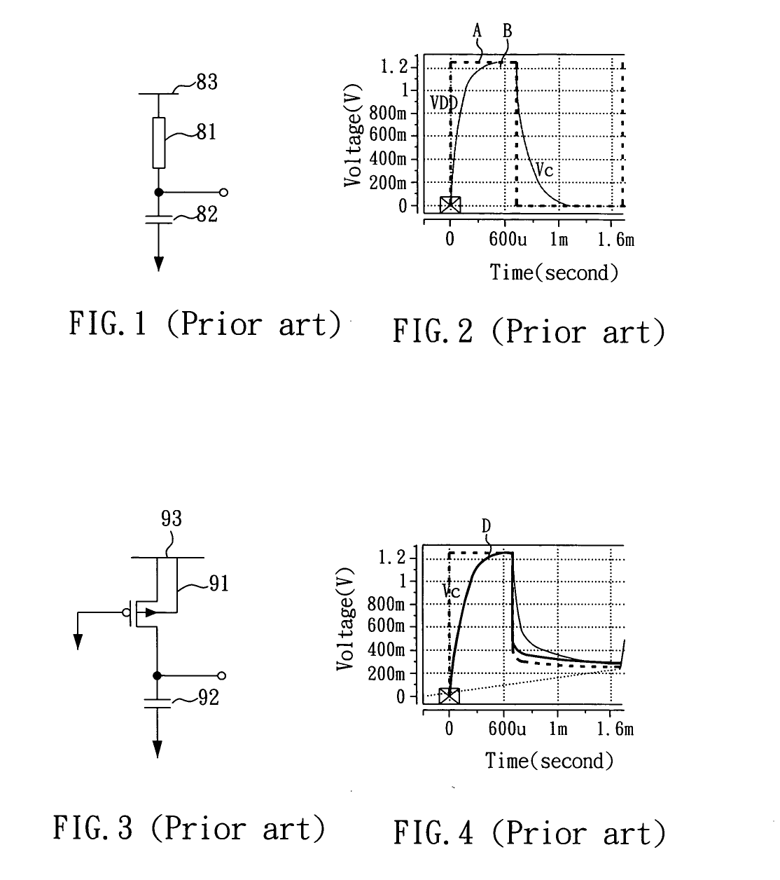

### DETAILED DESCRIPTION OF THE PREFERRED EMBODIMENT

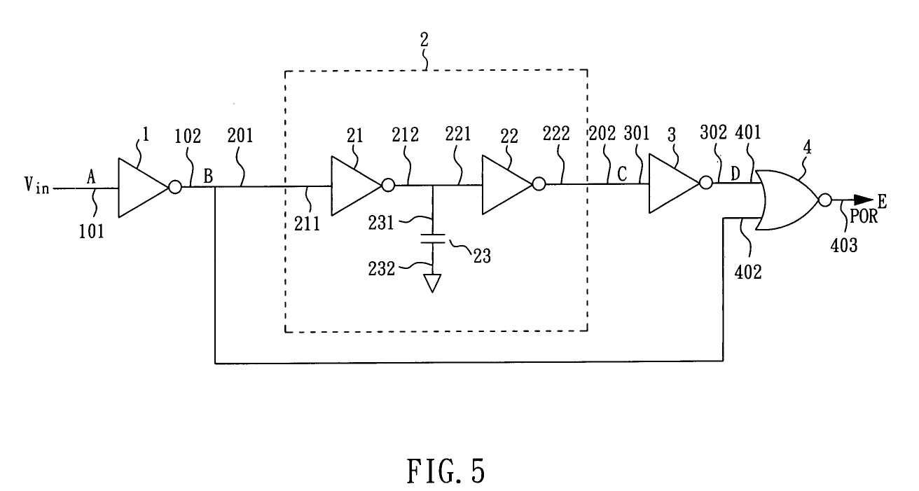

The present invention relates to a low-power power-on reset circuit. First referred to FIG. 5 of the system structure diagram of a preferred embodiment, the present invention comprises a NOT gate device 1, a time delay device 2, a wave shaping device 3 and a NOR gate device 4.

The NOT gate device 1 has an input 101 and an output 102. The input 101 of the NOT gate device 1 is configured to input an input voltage Vin.

The time delay device 2 has an input 201 and an output 202. The input 201 of the time delay device 2 is electrically connected to the output 102 of the NOT gate device 1. The time delay device 2 further includes a first NOT gate device 21, a second NOT gate 22 and a first capacitor device 23. The input 211 of the first NOT gate 21 is electrically connected the input 201 of the time delay device 2. The output 212 of the first NOT gate device 21 is electrically connected to one end 231 of the first capacitor 23 and the input 221 of the second NOT gate device 22 respectively. The other end 232 of the first capacitor device 23 is electrically connected to GND.

The wave shaping device 3 has an input 301 and an output 302. The input 301 of the wave shaping device 3 is electrically connected to the output 202 of the time delay device 2, such that the logic level of the output signals from the time delay device 2 can become much more precise.

The NOR gate device 4 has a first input 401, a second input 402 and an output 403. The first input 401 is electrically connected to the output 302 of the wave shaping device 3. The second input 402 is electrically connected to the output 102 of the NOT gate device 1. A power-on reset signal POR is outputted by the output 403 of the NOR gate device 4.

The main objective of the present invention is to provide a low-power power-on reset circuit that can be formed by a complementary metal oxide semiconductor (CMOS) to yield lower power consumption. Since the circuit is formed by the CMOS, it has an extremely low static current and extremely low power consumption, with which the circuit can tolerate power having relatively inferior quality, such that any heat dissipation would not become an issue, and the integration density can be increased accordingly. Further, the noise margin of the circuit can be increased. Since the output voltage of the CMOS mostly swings either at the high peak voltage or at the low peak voltage without yielding any medium voltage, the noise margin of the circuit is higher than that of a bipolar transistor. Moreover, in the present invention, the power voltage is not discharged through the resistors or the capacitors; therefore, the power consumed can be reduced.

In this embodiment, the NOT gate device 1, the time delay device 2, the wave shaping device 3 and the NOR gate device 4 are all implemented by the use of the integrated circuit layout. The NOT gate device 1, the first NOT gate device 21 and the second NOT gate device 22 of the time delay device 2 and the NOR gate device 4 are all complementary mental oxide semiconductor (CMOS) devices. An N-type metal oxide semiconductor field effect transistor (MOSFET) and a P-type MOSFET are provided in pair symmetrically. The N-type MOSFET has a gate, a source and a drain, and P-type has a gate, a source and a drain as well.

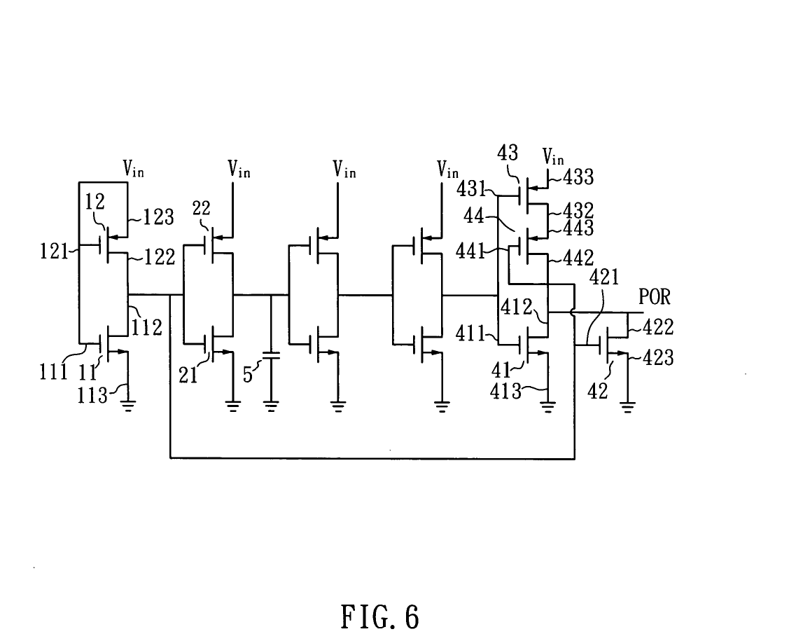

FIG. 6 is the circuit diagram of the embodiment of the present invention shown in FIG. 5. The NOT gate device 1 further includes the N-type MOSFET 11 and the P-type MOSFET 12. The input voltage Vin is inputted to the gate 111 of the N-type MOSFET 11 and the gate 121 of the P-type MOSFET and then outputted via the drain 112 of the N-type MOSFET 11 and the drain 122 of the P-type MOSFET. The source 113 of the N-type MOSFET 11 is coupled to GND, and the source 123 of the P-type MOSFET 12 is coupled to the power voltage. Since the first NOT gate device 21, the second NOT gate device 22 and the wave shaping device 3 are all identical to the NOT gate device 1, which is formed by the N-type MOSFET and the P-type MOSFET, the detail will not be further described again herein.

The NOR gate device 4 includes a first N-type MOSFET 41, a second N-type MOSFET 42, a first P-type MOSFET 43 and a second P-type MOSFET 44. An input signal is respectively coupled to the gate 411 of the first N-type MOSFET 41 and the gate 431 of the first P-type MOSFET, while another input signal is coupled to the gate 421 of the second N-type MOSFET 42 and the gate 441 of the second P-type MOSFET 44. An output signal is outputted via the drain 412 of the first N-type MOSFET 41 and the drain 422 of the second N-type MOSFET. The source 413 of the first N-type MOSFET 41 and the source 423 of the second N-type MOSFET 43 are coupled to GND. The source 433 of the first P-type MOSFET 43 is coupled to the power voltage. The drain 432 of the first P-type MOSFET 43 is coupled to the source 443 of the second P-type MOSFET 44. The drain 442 of the second P-type MOSFET 44 is coupled to the output of the NOR gate device 4.

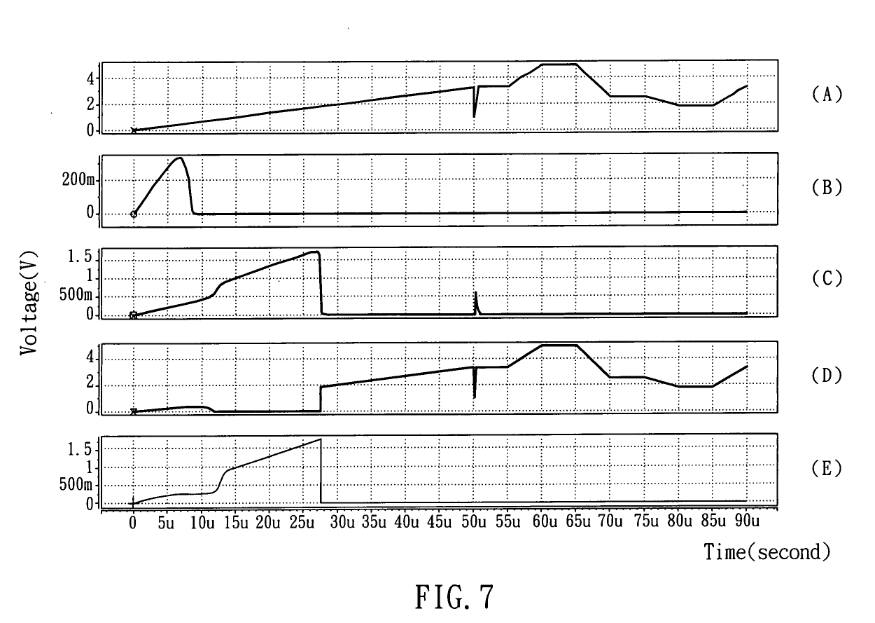

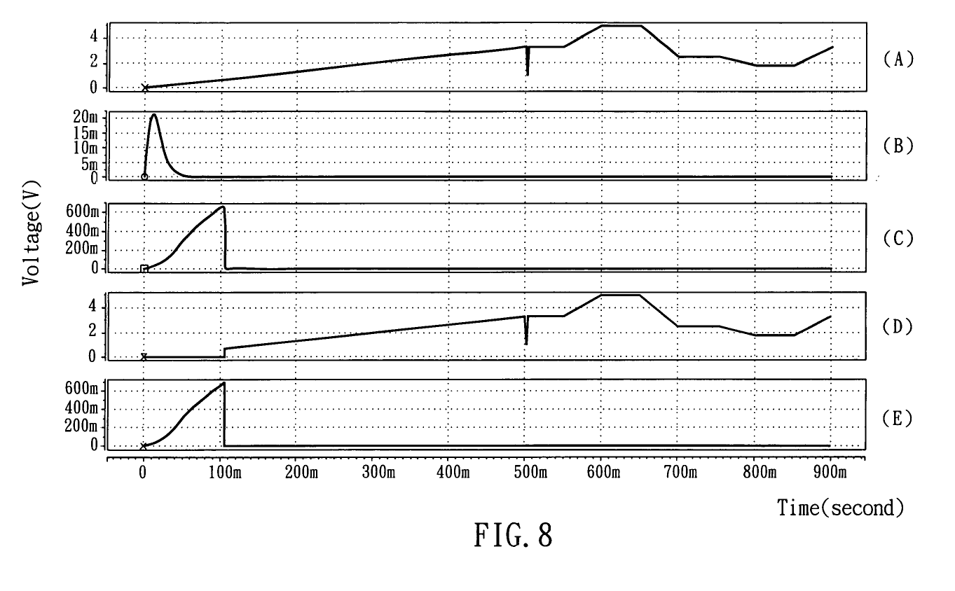

Also regarding the operation of the aforementioned circuit, FIG. 7 shows a set of partially magnified waveforms in accordance with the embodiment of the present invention, and FIG. 8 shows a set of waveforms in accordance with the embodiment of the present invention. Among the waveforms in FIG. 7 over a shorter period of time, diagram A depicts the waveform of the input voltage Vin; diagram B depicts the waveform at the output 102 of the NOT gate device 1; diagram C depicts the waveform at the output 202 of the time delay device 2; diagram D depicts the waveform at the output 302 of the wave shaping device 3; and diagram E depicts the waveform at the output 403 of the NOR gate device 4. From the diagrams, it can be seen that before the time at 10 μs, the power voltage Vin, though increased slowly, is not high enough to activate the NOT gate device 1. After 10 μs, the power voltage Vin rises to a positive logic level (Hi), and thus, the voltage is accordingly maintained at a negative logic level (Low) in diagram B. In diagram C, the capacitor 23 is charged with the power voltage Vin, reaching to Hi. Diagram E illustrates the waveform at the output of the NOR gate device 4; at 27 μs, the waveform in diagram B maintains at low while the waveform in diagram D rises to Hi, such that the waveform in diagram E maintains at the negative logical level. At 50 μs as the power voltage Vin drops abruptly, the output voltage does not seem to be affected. Similarly at 60 μs as the power voltage rises, the output voltage is still shown unaffected, achieving therefore an ideal power-on reset operation. FIG. 8 shows the waveforms over a longer period of time, from which it is obvious to observe that the embodiment enters the reset mode approximately after 100 ms, at which the changes in power or instant impulses do not cause any effect.

Also, of the low-power power-on reset circuit shown in FIG. 5, the time delay device 2 is formed by the first NOT gate device 21, the second NOT gate device 22 and the first capacitor device 23 to provide a time delay function. Yet in practice, in order to provide different timing delays, the low-power power-on reset circuit can further include multiple time delay devices 2 connected in series. The wave shaping device 3 is formed by a NOT gate device 3, and can also be formed by an odd numbered (3, 5, 7 or etc) of NOT gate devices connected in series to invert the input waveform.

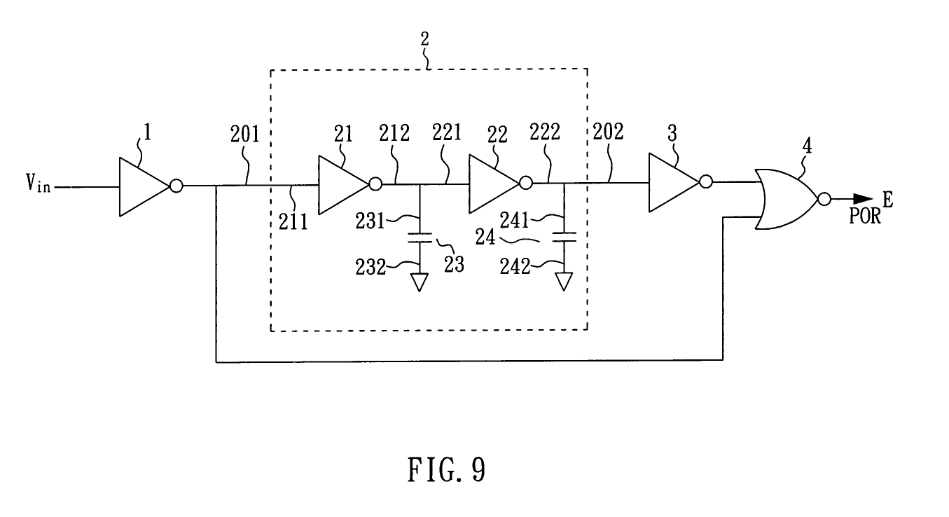

FIG. 9 is the system schematic diagram illustrating another embodiment of the present invention. This embodiment is similar to the previous one except the internal units within the time delay device 2. The time delay device 2 in this embodiment includes a first NOT gate device 21 and a first capacitor device 23, connected in series with a second NOT gate device 22 and a second capacitor device 24. That is, the input 211 of the first NOT gate device 21 is electrically connected the input 201 of the time delay device 2; the output 212 of the first NOT gate device 21 is electrically connected to one end of the first capacitor device 23 and the input 221 of the second NOT gate device 22 respectively; the output 222 of the second NOT gate device 22 is electrically connected to the output 202 of the time delay device 202 and one end of the second capacitor device 24 respectively; and the first capacitor device 23 and the other end of second capacitor device 24 are electrically connected to GND. Charging both the first capacitor device 23 and the second capacitor device 24 therefore provide time delaying, such that the circuit of this embodiment can also achieve the same objective as that in the previous embodiment.

Although the present invention has been explained in relation to its preferred embodiment, it is to be understood that many other possible modifications and variations can be made without departing from the scope of the invention as hereinafter claimed.

What is claimed is:

1. A low-power power-on reset circuit comprising:
a NOT gate device having an input and an output, the input of the NOT gate device being configured to input a power voltage;
at least one time delay device having an input and an output, the input of the time delay device being electrically connected to the output of the NOT gate device;
a wave shaping device having an input and an output, the input of the wave shaping device being electrically connected to the output of the time delay device; and
a NOR gate device having a first input, a second input and an output, the first input of NOR gate device being electrically connected to the output of the wave shaping device, and a power-on-reset signal being outputted by the output of the NOR gate device.

2. The low-power power-on reset circuit as claimed in claim 1, wherein the time delay device further comprises a first NOT gate device, a second NOT gate device and a first capacitor device, the input of the first NOT gate device is electrically connected to the input of the time delay device, the output of the first NOT gate device is electrically connected to one end of the first capacitor device and the input of the second NOT gate device respectively, while the other end of the first capacitor device is electrically connected to GND, the output of the second NOT gate device is electrically connected to the output of the time delay device.

3. The low-power power-on reset circuit as claimed in claim 1, wherein the NOT gate device further comprises an N type MOSFET and a P type MOSFET.

4. The low-power power-on reset circuit as claimed in claim 3, wherein the N type MOSFET comprises a gate, a source and a drain, the P type MOSFET has a gate, a source and a drain.

5. The low-power power-on reset circuit as claimed in claim 4, wherein the input of the NOT gate device is coupled to the gate of the N type MOSFET and the gate of the P type MOSFET.

6. The low-power power-on reset circuit as claimed in claim 4, wherein the output of the NOT gate device is coupled to the drain of the N type MOSFET and the drain of the P type MOSFET.

7. The low-power power-on reset circuit as claimed in claim 4, wherein the source of the N type MOSFET is coupled to GND, the P type MOSFET is coupled to the power voltage.

8. The low-power power-on reset circuit as claimed in claim 1, wherein the NOR gate device further comprises a first N type MOSFET, a second N type MOSFET, a first P type MOSFET and a second P type MOSFET.

9. The low-power power-on reset circuit as claimed in claim 8, wherein the first N type MOSFET has a gate, a source and a drain, and the first P type MOSFET has a gate, a source and a drain.

10. The low-power power-on reset circuit as claimed in claim 9, wherein the first input of the NOR gate device is coupled to the gate of the first N type MOSFET and the gate of the first P type MOSFET.

11. The low-power power-on reset circuit as claimed in claim 9, wherein the second input of the NOR gate device is coupled to the gate of the second N type MOSFET and the gate of the second P type MOSFET.

12. The low-power power-on reset circuit as claimed in claim 9, wherein the output of the NOR gate device is coupled to the drain of the first N type MOSFET and the drain of the second N type MOSFET.

13. The low-power power-on reset circuit as claimed in claim 9, wherein the source of the first N type MOSFET and the source of the second N type MOSFET are both coupled to GND.

14. The low-power power-on reset circuit as claimed in claim 9, wherein the source of the P type MOSFET is coupled to the power voltage.

15. The low-power power-on reset circuit as claimed in claim 9, wherein the drain of the first P type MOSFET is coupled to the source of the second P type MOSFET.

16. The low-power power-on reset circuit as claimed in claim 9, wherein the drain of the second P type MOSFET is coupled to the output of the NOR gate device.

17. The low-power power-on reset circuit as claimed in claim 1, wherein the time delay device further comprises a first NOT gate device, a second NOT gate device, a first capacitor device and a second capacitor device, the input of the first NOT gate device is electrically connected to the input of the time delay device, the output of the first NOT gate device is electrically connected to one end of the first capacitor and the input of the second NOT gate device respectively, the output of the second NOT gate device is electrically to the output of the time delay device and one end of the second capacitor respectively, while the other end of the first capacitor device and the other end of the second capacitor device are electrically connected to GND.

18. The low-power power-on reset circuit as claimed in claim 1, wherein the wave shaping device is a NOT gate device.

19. The low-power power-on reset circuit as claimed in claim 18, wherein the wave shaping device includes an odd numbered NOT gate devices connected in series.
